(19) United States
(12) Patent Application Publication
(10) Pub. No.: US 2018/0294696 A1
(43) Pub. Date: Oct. 11, 2018

(54) MEASURING COIL UNIT AND ELECTRIC MACHINE COMPRISING A MEASURING COIL UNIT OF THIS TYPE AND METHOD FOR DETERMINING OPERATING PARAMETERS OF AN ELECTRIC MACHINE

(71) Applicant: Universitaet Kassel, Kassel (DE)

(72) Inventors: Ludwig BRABETZ, Lehre (DE); Thomas WALDMANN, Witzenhausen (DE); Mohammed AYEB, Kassel (DE)

(73) Assignee: Universitaet Kassel, Kassel (DE)

(21) Appl. No.: 15/573,956

(22) PCT Filed: May 13, 2016
(86) PCT No.: PCT/EP2016/060888

§ 371 Date: Nov. 14, 2017

(30) Foreign Application Priority Data
May 15, 2015 (DE) 10 2015 107 666.7

(51) Int. Cl. H02K 11/225; H02K 11/25; G01R 31/34

(52) U.S. Cl. CPC H02K 11/225; G01R 31/343; H02K 11/25

(57) ABSTRACT

An electric machine, in particular an electric motor, comprising a stator and a rotor, which are separated from each other by an air gap, wherein a measuring coil unit comprising a number of measuring coils which are adjacent to each other is arranged in the air gap. The electric machine is characterised in that the measuring coils are arranged one behind the other in the axial direction in the air gap. The invention further relates to a measuring coil unit which can be inserted in an air gap of an electric machine of this type, and a method for determining operating parameters of an electric machine which has a measuring coil unit of this type.

The invention relates to a measuring coil unit for use in an air gap between a stator and a rotor of an electric machine. The measuring coil unit has a plurality of measuring coils disposed adjacent to each other. The invention also relates to an electric machine, in particular an electric motor, comprising a rotor and a stator which are separated from one another by an air gap, wherein such a measuring coil unit is arranged in the air gap. Furthermore, the invention relates to a method for determining operating parameters of an electric machine with a rotor and a stator as well as an intermediate air gap by means of such a measuring coil unit arranged in the air gap.

An electric machine of the type mentioned above can be designed as a generator or as an electric motor. In an electric machine, a generally multipolar rotor rotates in a magnetic field of an also generally multipolar stator. The pole faces of the rotor and the stator, which are opposite each other, are mutually separated by an air gap during their movement. In this case, the electric machine can be designed both as an external rotor, in which the stator is located on the inside and is surrounded by the rotor, or as an internal rotor, in which the rotor is located on the inside and is surrounded by an external stator.

In electric machines with high efficiency and high specific power, as are used in industrial and increasingly also mobile applications, measurement sensors (sensors) are usually used, which are used for monitoring purposes (monitoring) and for regulation purposes. In this case, sensors are used to measure a wide range of operating parameters.

The so-called polar wheel angle, which is the angle between an angle of rotation of the rotor and the orientation of the magnetic field resulting in the air gap from the superimposition of the magnetic field (rotor field) generated by the rotor and the magnetic field generated by the stator (stator field), is particularly relevant for controlling the electric machine. To determine the polar wheel angle, the rotor position and phase position of currents in the windings of the stator are measured for example. Different methods are established for measuring the rotor position. For example, optical position sensors or such based on the Hall effect are used, which are arranged outside the motor and measure an angle of rotation of the rotor relatively to the stator on the rotor axis. Such position sensors often operate digitally and supply position information incrementally or absolutely. In addition, magnetic or electromagnetic external sensors that operate in an analog manner are also known.

Sensors, which are mainly used for the purpose of monitoring, serve above all to recognize critical states of the machine in due time in order to be able to warn against these critical conditions or to be able to counteract them. In addition to measuring mechanical parameters such as vibrations, a temperature measurement is particularly relevant here. Exceeding temperature limits can result in loss of function and can even cause irreversible damage to sensitive components of the electric machine (insulation, adhesives, magnets, etc.). For measuring temperatures, ohmic temperature sensors are used for example, or semiconductor sensors, quartzes or radiation sensors.

Furthermore, it is known to indirectly draw conclusions on a temperature, for example by measuring temperature-dependent properties of materials, e.g. the coercivity of magnets or the relative dielectricity, measured on the basis of magnetic or capacitive measuring methods. Particularly difficult is the measurement of the rotor temperature. In laboratory systems or in large electric machines, complex radio-based measuring systems are used for this purpose, or only the surface temperature is determined by means of radiation sensors, or conclusions on the rotor temperature are drawn only indirectly via the measurement of temperature-dependent properties.

A method for measuring the rotational position of a rotor and the rotational speed of the rotor of an electric machine is known from the printed document DE 10 2005 050670 A1, in which a measuring unit is used which is arranged in the air gap between the rotor and the stator. The measuring unit consists of a thin circuit foil, on which a plurality of planar windings are arranged next to one another as measuring coils. The measuring coils are designed as concentric induction coils all lying in one plane. They are distributed on the circumference of the air gap of the machine to detect and process the induced voltages of the azimuthally distributed strands and poles of the machine.

The circuit foil is introduced in a radially circumferential manner into the air gap between stator and rotor and can extend over the entire length of the air gap in order to realize the largest possible winding surfaces and thus to maximize the amplitudes of the detected signals and to achieve a good signal-to-noise ratio. In each case, a plurality of the windings are interconnected in such a way that one or more measuring strings result which can be contacted from the outside. Voltages induced into the measuring strings during movement of the rotor relative to the stator provide conclusions about the position and speed of the rotor. The polare wheel angle itself cannot be determined solely from this measurement since, although information is obtained on the magnetic field which is set in the air gap, it does not contain information about how this is composed of the components of the stator field and the rotor field. The angular resolution obtainable in this method during the determination of the rotor position is dependent on the ratio of the number of measuring coils along the circumference of the air gap to the number of poles of the stator or rotor. The angular resolution is maximized if one measuring coil per pole is provided.

It is an object of the present invention to provide a possibility for determining operating parameters, in particular the rotor position and the polar wheel angle, for an electric machine with a high radial resolution. The resolution should in particular be greater than the angular distance between two adjacent poles of the electric machine.

This object is achieved by a measuring coil unit, an electric machine with a measuring coil unit and a measuring method for an electric machine having the features of the respective independent claim. Advantageous embodiments and further developments are the subject matter of the respective dependent claims.

An electric machine according to the invention of the type mentioned above is characterized in that the measuring coils are arranged one behind the other in the axial direction in the air gap. Due to the axial arrangement of the measuring coils, i.e. extending in the direction of a rotor axis, it becomes possible to determine additional information which, on the one hand, allows determining the polar wheel angle on the one hand and which leads to a higher angular resolution on the other hand.

In an advantageous embodiment, the electric machine has in each case a plurality of stator teeth in the region of a pole of the stator, wherein the measuring coils are arranged along one of the stator teeth and have a width which is less than or equal to a width of the stator tooth.

Since a plurality of stator teeth are located in the region of a stator pole, the width of the measuring coils is thus significantly smaller than the width of a stator pole whose width again corresponds to that of a rotor pole. By means of this embodiment of the measuring coil, the fraction induced by the rotor field can be separated from the fraction induced by the stator field in the measured voltage. When a rotor pole passes over the measuring coil, a signal peak (spike) is induced in the measuring coils, which overlays the periodic signal of the stator field, due to the small width of the measuring coil during the retraction as well as during the extension of the rotor pole. On the basis of the signal peak, the magnitude of the rotor field can be determined separately from the size of the stator field or the size of the overall field. As a result, both the rotor position and also the relative position of the entire air gap field relative to the rotor, i.e. the torque-determining polar wheel angle, can be determined.

In a further advantageous embodiment, the rotor of the electric machine has a plurality of mutually twisted segments. Preferably, at least one measuring coil is assigned to each of these segments. Particularly preferably, the at least one measuring coil associated with one of the segments is positioned such that it lies in the region of a magnetic field generated by the segment in question.

The segmentation of the rotor, combined with the measuring coil individually assigned to a segment, leads to a phase shift between two induced voltages of two adjacent measuring coils. This phase shift corresponds to the angle offset between two rotor segments. The more axially arranged measuring coils are used over the rotor segments, the more precisely rotor position and rotor angle are determined and the ratio of useful signal to noise is further improved. In addition, the parallel measurement over the rotor segments allows an elimination of cross-sensitivities, e.g. the temperature on the magnetization, as well as the aforementioned unambiguous separation of the fractions of the measuring voltage induced by the rotor and stator field even in the case that the progressions of both fractions are similar, e.g. both sinusoidal. The twisting of the segments relative to one another can take place step by step, but also continuously. A continuous segmentation exists for example in a squirrel-cage rotor of an asynchronous machine.

Particularly preferably, the further developments described above are combined by using a segmented rotor with measuring coils assigned to the segments, wherein the at least one measuring coil assigned to one of the segments is arranged on the stator tooth opposite the respective segment. This results in the best possible angular resolution and the possibility to determine the polar wheel angle with a good signal-to-noise ratio.

A measuring coil unit according to the invention for use in an air gap lying between a stator and a rotor of an electric machine has a plurality of measuring coils lying next to one another and is characterized in that the measuring coils are arranged on an elongate carrier and connections of the measuring coils are led to connection contacts which are arranged on a transverse side of the carrier. Such a measuring coil unit can be arranged and contacted axially in the air gap in an electric machine. The advantages described in connection with the electric machine are obtained.

In an advantageous embodiment of the measuring coil unit, each of the measuring coils has at least two superimposed planar windings, wherein one of the windings is formed on an upper side of the carrier and one winding is formed on a lower side of the carrier. Each of the measuring coils is preferably contactable separately via the connection contacts. In this configuration of the measuring coil unit, the feed lines from the connection contacts to the individual measuring coils can be arranged one above the other once on the lower side and once on the upper side of the measuring coil unit. Voltages induced in the feed lines on the upper and lower side then cancel each other out and are no longer detected as artefacts.

In a further advantageous embodiment of the measuring coil unit, the carrier is a flexible film. Such a flexible film can be formed in a particularly thin way and can thus also be arranged in a narrow air gap. Furthermore, the measuring coil unit preferably has electronic components for processing and/or evaluating a measuring signal of the measuring coils, whereby signal processing can be effected in closest proximity to the measuring coils with the lowest possible interference.

A method according to the invention for determining operating parameters of an electric machine with a stator and a rotor with a plurality of mutually twisted segments as well as an interposed air gap, in which a measuring coil unit is arranged which has measuring coils lying one behind the other in the axial direction, comprises the following steps: Induced signals from at least two of the measuring coils associated with different segments are detected. A rotational position of the rotor relative to the stator and/or a polar wheel angle is then determined by taking into account the twisting of the segments relative to each other. Here, too, the advantages explained in connection with the electric machine are obtained.

In an advantageous embodiment of the method, at least one measuring coil is assigned to each segment, and at least a number of induced signals are recorded and evaluated which corresponds to the number of segments of the rotor. In this way, a best possible angular resolution is achieved.

In a further advantageous embodiment of the method, a temperature of the stator is determined from an ohmic resistance of at least one of the measuring coils. The resistance measurement is preferably repeated in at least two different measuring currents, wherein a value correlated with a convection in the air gap is determined from a difference between the resistances determined for different measuring currents. By means of the resistance measurement, the operating parameters of stator temperature and convection in the air gap, which are otherwise difficult to access, can also be determined in an axially resolved manner at the positions of the individual measuring coils.

The invention is explained in more detail below with reference to an exemplary embodiment shown in the drawings, wherein:

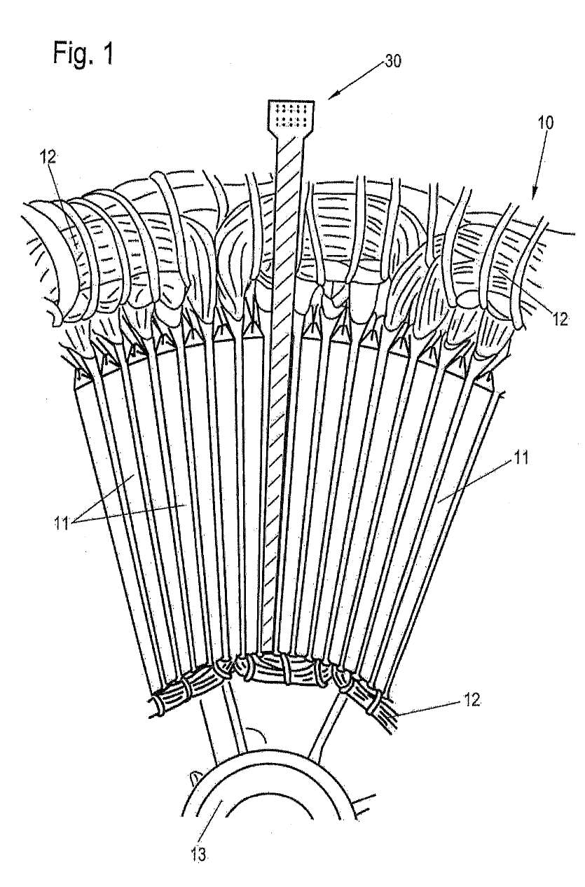

FIG. 1 shows a perspective view of a part of a stator of an electric machine with a measuring coil unit;

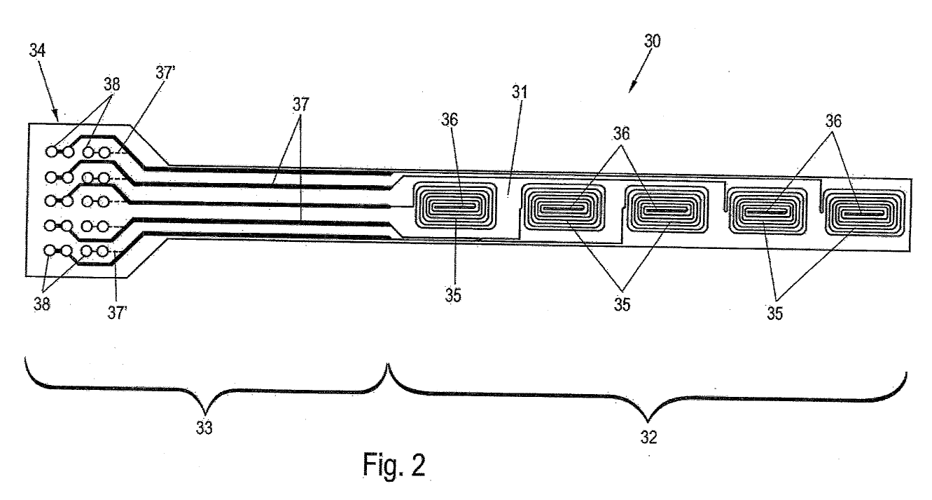

FIG. 2 shows a top view of a measuring coil unit, for use in an air gap of an electric machine;

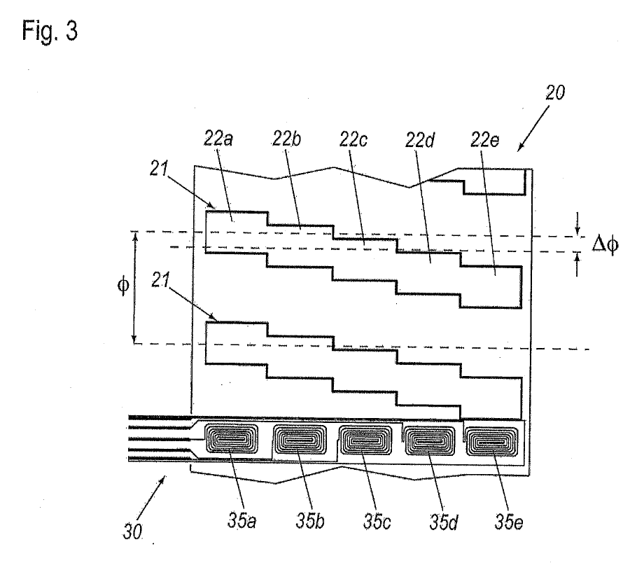

FIG. 3 shows a schematic view of a section of the measuring coil unit according to FIG. 2 with a section of a rotor.

FIG. 1 shows a perspective view into a stator 10 of an electric machine. Of the stator 10, only a portion along its circumference is reproduced. An associated rotor is not shown in this illustration in order to allow a view of the stator 10.

A plurality of stator teeth 11 extending in the axial direction can be seen along an inner jacket surface of the stator 10. The stator teeth 11 are the part of a stator lamination stack visible in this perspective. Wires of a stator winding 12 extend in grooves of the stator lamination stack, which separate the stator teeth 11 from each other. A magnetic stator field, referred to as a stator field, is produced by the stator winding 12 during operation of the electric machine. The stator field has a plurality of poles circumferentially along the jacket surface, wherein a plurality of the stator teeth 11 is located respectively in the region of each pole.

In the lower part of the drawing, radially extending housing bars can be seen, which connect the stator housing to a central bearing seat 13. In the assembled state of the electric machine, a bearing for an axis of the rotor is arranged in this bearing seat 13.

A measuring coil unit 30 is arranged on one of the stator teeth 11. The measuring coil unit 30 extends along the entire length of the stator tooth 11 and is thus aligned in the axial direction parallel to the rotor axis which is not visible here. The measuring coil arrangement 30 is adapted in its width to the width of the stator tooth 11 and is thus significantly smaller than the width of a pole. At the end of the respective stator tooth 11 which lies at the top in FIG. 1, the measuring coil unit 30 projects beyond the stator tooth 11 and the winding 12 and opens into a connection region.

The measuring coil unit 30 is preferably embodied as a thin flexible film, which is fixed on the stator tooth 11, for example glued thereon. The upper end protruding beyond the stator tooth 11 can be tilted backwards due to the flexibility in order to be able to contact the connection region in the assembled state of the electric machine. The thickness of the measuring coil unit 30 is preferably in a range of less than 200 μm (micrometer), more preferably less than 100 μm, in order to be able to use the measuring coil unit 30 also in an electric machine having a narrow air gap between the rotor and the stator.

FIG. 2 shows in more detail and in a plan view a measuring coil unit 30, as can be used, for example, with a stator 10 according to FIG. 1. The embodiment of the measuring coil unit 30 shown in FIG. 2 basically corresponds essentially to the measuring coil unit 30 used in FIG. 1. In order to be able to reproduce details better, a measuring coil unit 30 is shown in FIG. 2 which deviates from FIG. 1 and is wider in its length than in the case of the embodiment of FIG. 1.

The measuring coil unit 30 has an elongated carrier 31, which can be divided into a coil section 32 and a connecting section 33 adjoining the latter. At the end opposite the coil section 30, the connecting section 33 opens into a connection head 34.

The coil section 32 is that part of the measuring coil unit 30 which extends along one of the stator teeth 11 (see FIG. 1) and is fixed thereon, preferably glued thereon. A plurality of five measuring coils 35 is arranged along the coil section 32, which coils are arranged evenly at a distance from one another in the longitudinal direction of the measuring coil unit 30 one behind the other. The measuring coils 35 are arranged as spiral-shaped planar coils with rectangular windings. Each of the measuring coils is preferably of two-layer design, wherein a first layer of FIG. 2 is visible and a second layer with the same winding shape is arranged on the rear side of the measuring coil unit 30 which is not visible in FIG. 2. A through-connection 36 is provided in the central region of each measuring coil 35 for connecting the two layers to one another.

Each of the measuring coils 35 is connected to separate feed lines 37 with corresponding connection contacts 38 in the connection head 34 in order to be able to be contacted from the outside. The connection contacts are thus arranged on a transverse side of the carrier, whereby all measuring coils 35 can be contacted outside the air gap. Preferably, all the connection contacts are located on a transverse side. Alternatively, and in particular in electric machines of long design and/or in the case of a large number of measuring coils 35, both transverse sides can also be provided with connection contacts 38.

A respective feed line 37 serving as a connection of a measuring coil 35 extends here visibly on the upper side of the measuring coil unit 30. A second feed line is arranged on the lower side of the measuring coil unit 30 which is not visible here. The feed lines 37 on the upper and lower side of the measuring coil unit 30 extend as congruently as possible, as a result of which the voltages induced in the feed lines 37 on the upper and lower side cancel each other out. In the region of the connection contacts 38, short sections of the feed lines running on the lower side of the measuring coil unit 30 are symbolized in dashed lines as feed lines 37′.

With a thin flexible foil as carrier 31, the measuring coil unit 30 can advantageously be designed as a flexible printed circuit board (FPC). Both the measuring coils 35 and the feed lines 37 are in this case worked out of a thin-metal layer applied to the carrier 31, preferably in an etching process. On the upper and lower side of the measuring coil unit 30, an insulating final layer, e.g. an insulating lacquer, is preferably applied after structuring the measuring coils 35 and the feed lines 37. In alternative embodiments of the measuring coil unit 30, other methods forming conductor tracks are used. It is conceivable in an alternative embodiment that at least parts of the measuring coil unit 30, e.g. the measuring coils 35, are also applied directly, i.e. without the carrier 31, onto the stator tooth 11.

In alternative embodiments, a more than two-layer measuring coil 35 can also be provided, for example by using a stack of two or more carrier films which form the carrier 31 placed on top of one another. A further coil layer can be formed with each additionally placed film layer. For example, a three-layer measuring coil 35 can be formed with two films placed one on top of the other as a carrier 31, and a four-layer measuring coil 35 can be formed with three superimposed films. The greater the number of layers of the coil, the higher the induced voltages and the simpler or preciser an evaluation can take place. The number of film layers, and thus the layers of the measuring coils 35 is limited however by the maximum thickness of the measuring coil unit 30 and of the air gap.

The mode of operation of the measuring coil unit 30 according to the invention will be explained below with reference to FIG. 3. FIG. 3 shows, in a schematic representation, the measuring coil unit 30 of FIG. 2 without the stator 10 in front of a rotor 20 which moves relative to the stator (not shown) and thus also relative to the illustrated measuring coil unit 30. With respect to the rotor 20, only a small section of its jacket surface is shown in FIG. 3 above the measuring coil unit 30 in a developed projection. During operation, this jacket surface moves beneath the measuring coil unit 30 when the rotor 20 rotates.

According to the invention, the measuring coil unit 30 is used in conjunction with an electric machine which has a segmented rotor 20. In such a segmented rotor 20, rotor poles 21 are not designed to extend straight and parallel to the rotor axis, but are divided into a plurality of segments 22a-22e, which are each offset from one another by a specific angular offset Δϕ.

FIG. 3 shows this for two rotor poles 21. The two rotor poles 21 have an angular offset of ϕ relative to each other, which also the poles of the associated stator 10 have relative to one another. The segments 22a-22e of the two illustrated rotor poles 21 also show this same offset ϕ with respect to each other.

The offset of the quantity Δϕ existing between adjacent segments 22a to 22b or 22b to 22c etc. also exists between the last segment 22e of a rotor pole 21 and the first segment 22a of a rotor pole 21 adjacent thereto. The angle offset ϕ between two rotor poles 21 are thus equally divided in this exemplary embodiment into five equally large angular displacements Δϕ=1/5(ϕ).

It is noted that the number and type of segments 22a-22e is purely exemplary in the segmented rotor 20. Segmentation can also be provided in more or less than the specified five segments. Furthermore, the angular offset Δϕ between adjacent segments as well as between a last segment of a rotor pole and the first segment of a next rotor pole is not necessarily exactly as large as an offset between adjacent segments.

When the rotor 20 is rotated relative to the stator 10 and accordingly when the rotor poles 21 are moved relative to the measuring coil unit 30, the respective magnetic field of a segment 22a-22e of a rotor pole 21 reaches the correspondingly associated measuring coil 35 not at the same time, but with corresponding angular offset Δϕ and thus with accompanying time offset. For the sake of simpler correlation, the measuring coils 35 in FIG. 3 are also distinguished from one another by an index a-e.

When the rotor 20 is rotated, a primarily periodic signal is induced in the individual measuring coils 35a-35e, which reflects the changing magnetic fields at the location of the respective measuring coil 35a-e. Since as a result of the induction the respective measuring coil 35a-35e does not provide absolute values of the fields, but a voltage proportional to the change in the fields, both the magnitude of the air gap magnetic field and the rotor movement are relevant for the signal.

Each of the signals induced in the measuring coils 35a-35e shows a periodic change with a length of 2ϕ, relating to the angular movement of the rotor 20. However, the individual signals of the measuring coils 35a-35e are phase-offset relative to each other due to the angular offset Δϕ. In a measuring method according to the invention, the signals of the measuring coils 35a-35e are compared with one another. As a result, it is possible to track the rotational movement of the rotor 20 with an angular resolution which is higher by a factor which corresponds to the number of the segments 22, which in this case is the factor of 5, than would be the case in the evaluation of the signal of only one of the measuring coils 35.

In a detailed evaluation of the signals of the individual measuring coils 35a-35e, it should be noted that the signals induced in the individual measuring coils 35a-e overlap influences of the rotor field and of the stator field non-linearly in terms of their shape and their course. With knowledge of the magnetic saturation and hysteresis, the linear overlap can be calculated. In addition, the width of the measuring coils 35 is in the range of the width of a stator tooth 11. Since a plurality of stator teeth 11 lies in the region of a stator pole, the width of the measuring coils 35 is thus significantly smaller than the width of a stator pole and thus of the rotor pole 21. The proportion induced by the rotor field can be separated from the portion induced by the stator field in the measured voltage by this arrangement of the measuring coil 35. When a rotor pole 21 passes over the measuring coil 35, a signal peak (spike) is induced in the measuring coil 35, which overlays the periodic signal of the stator field, due to the small width of the measuring coil 35 during the retraction as well as during the extension of the rotor pole 21. On the basis of the signal peak, the magnitude of the rotor field can be determined separately from the size of the stator field or the size of the overall field. As a result, both the rotor position and also the relative position of the entire air gap field relative to the rotor, i.e. the torque-determining polar wheel angle, can be determined. In the case of a measuring coil whose width is not less than the width of a rotor pole, the signal peak cannot be observed separately, but is contained in a non-separable manner in the total signal.

The rotor position can be determined even more precisely by means of the axially arranged measuring coils 35 and by using the rotor incline, since the phase shift between two induced voltages of two adjacent measuring coils 35a-35e corresponds to the angular offset Δϕ between two rotor segments 22a-22e. The more axially arranged measuring coils 35a-35e are used over the rotor segments 22a-22e, the more precisely the rotor position and polar wheel angle are determined and the ratio of useful signal to noise is further improved. In addition, the parallel measurement over the rotor segments 22a-22e allows the elimination of cross-sensitivities, e.g. the temperature on the magnetization, as well as the already above mentioned clear separation of the components of the measuring voltage induced by the rotor and stator field, even in the case that the progressions of both components are similar, i.e. both sinusoidal.

In contrast to an external measurement of the rotational position of the rotor 20, the presented internal measurement additionally offers the advantage that the position is not determined on the basis of the position of mechanical components, for example armature plates or the like, but the position which refers to the relative position of the magnetic fields generated by the stator and the rotor. For controlling a motor as an electric machine, this is the relevant variable. Thus, not only the rotor position but also the polar wheel angle is determined directly.

In a further embodiment of an electric machine with measuring coil unit 30, such a measuring coil unit 30 is provided several times. By arranging a plurality of measuring coil units 30, a higher signal strength can be achieved, for example, by means of a series connection of measuring coils 35a-35e, which are respectively assigned to the same segment 22a-22e.

Furthermore, it has been recognized that individual rotor poles 21, when moved past a measuring coil 35a-35e, lead to slightly different induced voltage fluctuations and/or voltage amplitudes, even under otherwise identical conditions. The individual rotor poles 21 thus have a type of signature by which they can be identified. A consideration of this signature during the evaluation makes it possible to detect the movement of the rotor 20 in relation to the stator 10 not only relative but also in absolute positions. The security with which this detection can be performed increases when there are several measuring coil units 30 which are evaluated separately.

An evaluation of the recorded measuring signals can take place externally, for example by using analog and/or digital signal filters and amplifiers. In particular, a digital signal processor is suitable for the evaluation. A first signal processing can take place in this case by means of an evaluation circuit, which is integrated on the carrier 31 of the measuring coil unit 30, preferably in the region of the connecting section 33.

In addition to the primary field of application of the measuring coil unit 30 for determining the position or movement of the rotor 20 in relation to the stator 10, further operating parameters of an electric machine can be detected additionally or alternatively by means of the measuring coil unit 30.

In a further embodiment of a measuring method of operating parameters for an electric machine according to the invention, the ohmic resistances of the measuring coils 35 of a measuring coil unit 30 are determined. In the case of known resistance temperature coefficient of the measuring coils 35, conclusions can be drawn from the resistance on a temperature of the measuring coil 35. When the resistance measurement for determining the resistance of the measuring coils 35 is carried out with a low measuring current, this measuring current has no influence on the temperature of the measuring coil 35. Thus, the measured temperature reflects the temperature of the stator tooth 11, on which the measuring coil 35 is arranged. A measurement with different measuring coils 35a-35e positioned differently in the axial direction provides information about a temperature distribution along the stator tooth 11.

The resistance measurement is unproblematic for a stationary, non-energized electric machine. When the machine is rotating and thus periodic voltages are induced in the measuring coils 35 at the same time, it is necessary to determine their equal and mean value fractions for resistance measurement.

In a further development of the described method, the resistance of the measuring coils 35 is determined as before with a low and subsequently with an increased measuring current. The measurement with a low measuring current supplies, as described above, the temperature of the measuring coil 35 based on the temperature of the stator tooth 11.

During the temperature measurement with increased measuring current, the temperature of the measuring coil 35 is increased by introducing electrical leakage current due to the higher measuring current. The obtained increased temperature or the time sequence with which the temperature is increased provide information about the heat dissipation at the location of the measuring coil 35. This heat dissipation at the location of the measuring coil 35 is determined by essentially two components, one of which is provided in heat conduction into the stator tooth 11. A second component is the heat emission from the measuring coil 35 into the air gap, which is mainly dependent on air convection in the air gap. From comparative measurements with the engine at rest, the heat component conducted into the stator tooth 11 can be determined and stored depending on the temperature. When measuring with rotating rotor 20, this component can be extracted, so that the described method can determine information about the convection in the air gap, which also occurs in an axially spatially resolved manner at the position of the different measuring coils 35a-35e.

A further additional determination of operating parameters of an electric machine, in particular of an electric motor, can be carried out if during a rotation of the rotor 20 in the stator 10 the amplitudes of the currents in the rotor windings and the stator windings are constant. Such an operating state frequently occurs in the case of an electric motor when the drive and load conditions are not rapidly changing. If the amplitude of the voltage signals of the measuring coils 35 varies during such a cycle, this indicates asymmetries in the magnetization of permanent magnets of the armature 20 of the electric motor.

Such a measurement is preferably carried out when the temperature of the rotor 20 is known. For this purpose, use can be made of the fact for example that before start-up, after a longer period of standstill of the motor, the assumption is justified that the temperature of the rotor 20 is equal to the easily measurable temperature of the stator 10 and equal to the ambient temperature. If the described measurement of the asymmetry of the magnetization is then additionally carried out during operation of the motor, changes in the magnetization can be used inversely in order to draw conclusions on a temperature of the magnets which otherwise cannot be measured or can only be measured with great effort.

However, a change in the magnetization during operation can also be due to an irreversible demagnetization of the magnets, for example by an overtemperature. However, irreversible demagnetization of this type generally does not affect all magnets simultaneously and to the same extent, so that demagnetization can usually be distinguished from a normal temperature effect.

Furthermore, it is advantageous to repeatedly carry out a measurement of the magnetization and to consider the time course of the change in a magnetization. While a temperature change is a dynamic process which develops dependent on operating conditions which are also known, such as current supply and load, demagnetization is usually only revealed in operating states of overload. A continuous observation taking into account the operating states of the electric motor permits a distinction between a temperature-dependent and reversible change in the magnetization of the individual permanent magnets and irreversible demagnetization.

In a further measuring method according to the invention, the measuring coils 35 of the measuring coil unit 30 are supplied with a pulse, for example a square pulse. By means of this pulse, the measuring coils 35 themselves generate a magnetic field which overlaps with the magnetic field of the permanent magnets of the rotor 20. It is assumed in this case that the rotor 20 is at a standstill. Immediately following the current pulse through the measuring coils 35, the induction signal induced in the measuring coil 35 and decaying according to the Lenz rule is recorded. The shape and time constant with which this induction signal decreases is indicative of the magnetic resistance of the environment of the measuring coil 35. This magnetic resistance is significantly determined by the permanent magnet in the rotor 20. In the case of existing asymmetries of the permanent magnets, these asymmetries are reflected in the behavior of the induction signal in the measuring coil 35. Also with regard to their magnetic resistance and their direction of magnetization (north pole, south pole), the permanent magnets consequently carry a signature. In the case of a known signature of the individual permanent magnets, a position detection of the position of the rotor 20 relative to the stator 10 can also take place in the stationary state of the rotor.

### LIST OF REFERENCE NUMERALS

10 Stator
11 Stator tooth
12 Stator winding
13 Bearing seat
20 Rotor
21 Rotor pole
22a-e Segment
30 Measuring coil unit
31 Carrier
32 Coil section
33 Connecting section
34 Connection head
35, 35a-e Measuring coil
36 Through-connection
37 Feed line
38 Connection contact
ϕ Angle between two rotor poles
Δϕ Angular offset between two segments

1: An electric machine, in particular an electric motor, comprising a stator (10) and a rotor (20) which are separated from one another by an air gap, wherein a measuring coil unit (30) having a plurality of measuring coils (35, 35a-35e) disposed adjacent to each other are arranged in the air gap, wherein the measuring coils (35, 35a-35e) are arranged in the axial direction one behind the other in the air gap.

2: The electric machine according to claim 1, comprising a plurality of stator teeth (11) in the region of a pole of the stator (10), wherein the measuring coils (35, 35a-35e) are arranged along one of the stator teeth (11) and have a width which is less than or equal to a width of the stator tooth (11).

3: The electric machine according to claim 1, wherein said rotor (20) comprises a plurality of mutually twisted segments (22a-22e).

4: The electric machine according to claim 3, wherein at least one measuring coil (35, 35a-35e) is assigned to each segment (22a-22e).

5: The electric machine according to claim 4, wherein the at least one measuring coil (35, 35a-35e) assigned to one of the segments (22a-22e) is positioned in such a way that said coil lies in the region of a magnetic field generated by the respective segment (22a-22e).

6: The electric machine according to claim 2, wherein the at least one measuring coil (35, 35a-35e) assigned to one of the segments (22a-22e) is arranged on the stator tooth (11) opposite the respective segment (22a-22e).

7: A measuring coil unit (30) for use in an air gap disposed between a stator (10) and a rotor (20) of an electric machine, comprising several measuring coils (35, 35a-35e) disposed adjacent to each other, wherein the measuring coils (35, 35a-35e) are arranged on an elongate carrier (31) and connections of the measuring coils (35, 35a-35e) are guided to connection contacts (38) arranged on a transverse side of the carrier (31).

8: The measuring coil unit (30) according to claim 7, wherein each of the measuring coils (35, 35a-35e) has at least two superimposed planar windings, with one of the windings being formed on an upper side of the carrier (31) and one of the windings on a lower side of the carrier (31).

9: The measuring coil unit (30) according to claim 7, wherein each of the measuring coils (35, 35a-35e) can be contacted separately via the connection contacts (38).

10: The measuring coil unit (30) according to claim 7, wherein the carrier (31) is a flexible film.

11: The measuring coil unit (30) according to claim 7, comprising electronic components for processing and/or evaluating a measuring signal of the measuring coils (35, 35a-35e).

12: A method for determining operating parameters of an electric machine, comprising a stator (10) and a rotor (20) having a plurality of mutually twisted segments (22a-22e) and an air gap which is located therebetween and in which a measuring coil unit (30) is arranged which comprises measuring coils (35, 35a-35e) lying one behind the other in the axial direction, comprising the following steps:
detecting induced signals from at least two of the measuring coils (35, 35a-35e) assigned to different segments (22a-22e); and
determining a rotational position of the rotor (20) relative to the stator (10) and/or a polar wheel angle taking account of the twisting of the segments (22a-22e) relative to one another.

13: The method according to claim 12, wherein at least one measuring coil (35, 35a-35e) is assigned to each segment (22a-22e), and at least one number of induced signals is recorded and evaluated which corresponds to the number of segments (22a-22e) of the rotor (20).

14: The method according to claim 12, wherein a temperature of the stator (10) is determined from an ohmic resistance of at least one of the measuring coils (35, 35a-35e).

15: The method according to claim 14, wherein the resistance measurement is repeatedly carried out with at least two different measuring currents and a value correlated with a convection in the air gap is determined from a difference of the resistances determined for different measuring currents.
